(19) United States
(12) Patent Application Publication
(10) Pub. No.: US 2015/0084035 A1
(43) Pub. Date: Mar. 26, 2015

(54) THIN FILM TRANSISTOR AND METHOD OF MANUFACTURING THE SAME

(71) Applicant: Samsung Display Co., Ltd., Yongin-city (KR)

(72) Inventors: Dong Jo Kim, Yongin-city (KR); Ji Seon Lee, Yongin-city (KR); Deuk Myung Ji, Yongin-city (KR); Yoon Ho Khang, Yongin-city (KR); Kyung Seop Kim, Yongin-city (KR); Byeong-Beom Kim, Yongin-city (KR); Joon Yong Park, Yongin-city (KR)

(73) Assignee: Samsung Display Co., Ltd., Yongin-city (KR)

(21) Appl. No.: 14/261,935

(22) Filed: Apr. 25, 2014

(30) Foreign Application Priority Data
Sep. 23, 2013 (KR) 10-2013-0112778

(51) Int. Cl. H01L 29/786; H01L 29/51; H01L 29/66

(52) U.S. Cl. CPC H01L 29/78606; H01L 29/7869; H01L 29/66969; H01L 29/513; H01L 29/517; H01L 29/518
USPC 257/43; 438/104

(57) ABSTRACT

A thin film transistor includes: a substrate; an oxide semiconductor layer disposed on the substrate; a source electrode and a drain electrode each connected to the oxide semiconductor layer and facing each other with respect to the oxide semiconductor layer; an insulating layer disposed on the oxide semiconductor layer; and a gate electrode disposed on the insulating layer. The insulating layer includes a first layer that includes silicon oxide (SiOx), a second layer that is a hydrogen blocking layer, and a third layer that includes silicon nitride (SiNx). The first, second and third layers are sequentially stacked.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims priority to, and the benefit of, Korean Patent Application No. 10-2013-0112778 filed in the Korean Intellectual Property Office on Sep. 23, 2013, the entire contents of which are incorporated herein by reference.

### BACKGROUND

1. Field

The present disclosure relates to a thin film transistor and a method of manufacturing the same.

2. Description of the Related Technology

A flat panel display, such as, for example, a liquid crystal display (LCD), an organic light emitting diode display (OLED display), and an electrophoretic display, and a plasma display, typically includes a plurality of pairs of field generating electrodes and an electro-optical active layer interposed therebetween. The liquid crystal display includes a liquid crystal layer as the electro-optical active layer and the organic light emitting display includes an organic emission layer as the electro-optical active layer. One of the pair of field generating electrodes is generally connected to a switching element to receive an electrical signal and the electro-optical active layer converts the electrical signal into an optical signal to display an image.

The flat panel display may include a display panel on which a thin film transistor is formed. A thin film transistor display panel is patterned with electrodes of several layers, semiconductors, and the like, and the patterning process generally uses a mask.

The semiconductor is an important factor in determining characteristics of the thin film transistor. As the semiconductor, amorphous silicon has been mainly used, but the amorphous silicon has low charge mobility and therefore has a limitation in manufacturing a high-performance thin film transistor. Further, in the case of using polysilicon, the charge mobility is increased and thus the high-performance thin film transistor is easily manufactured, but the polysilicon is expensive and has low uniformity and therefore has a limitation in manufacturing a large thin film transistor display panel.

The above information disclosed in this Background section is only for enhancement of understanding of the background of the invention and therefore it may contain information that does not form the prior art that is already known in this country to a person of ordinary skill in the art.

### SUMMARY OF CERTAIN INVENTIVE ASPECTS

The present disclosure has been made in an effort to provide a thin film transistor with improved reliability and a method of manufacturing the same.

One embodiment provides a thin film transistor, including: a substrate; an oxide semiconductor layer disposed on the substrate; a source electrode and a drain electrode each connected to the oxide semiconductor layer and facing each other with respect to the oxide semiconductor layer; an insulating layer disposed on the oxide semiconductor layer, the insulating layer comprising a first layer, a second layer, and a third layer sequentially stacked, wherein the first layer comprises silicon oxide (SiOx), the second layer is a hydrogen blocking layer and the third layer comprises silicon nitride (SiNx); and a gate electrode disposed on the insulating layer.

The second layer may include aluminum oxide (AlOx).

The third layer may be thicker than the first layer.

Edge boundaries between the insulating layer and the gate electrode may be aligned with each other.

Edge boundaries between the gate electrode and the oxide semiconductor layer may be aligned with each other.

The source electrode and the drain electrode may each include a material obtained by reducing a material forming the oxide semiconductor layer.

The oxide semiconductor layer, the source electrode and the drain electrode may be disposed at a same layer.

The thin film transistor may further include: an interlayer insulating layer disposed on the gate electrode, in which the source electrode and the drain electrode may be disposed on the interlayer insulating layer and each of the source electrode and the drain electrode may be connected to the oxide semiconductor layer through a respective contact hole which is formed on the interlayer insulating layer.

Edge portions of each of the source electrode and the drain electrode may overlap the gate electrode.

The thin film transistor may further include: a buffer layer disposed between the substrate and the oxide semiconductor layer.

Another embodiment provides a method of manufacturing a thin film transistor, including: forming an oxide semiconductor layer on a substrate; forming an insulating layer by sequentially stacking a first layer, a second layer, and a third layer on the oxide semiconductor layer, wherein the first layer is formed by chemical vapor deposition, the second layer is formed by sputtering or atomic layer deposition, and the third layer is formed by chemical vapor deposition; forming a gate electrode on the insulating layer; and forming a source electrode and a drain electrode connected to the oxide semiconductor layer and facing each other with respect to the oxide semiconductor layer.

The first layer may include silicon oxide (SiOx), the third layer may include silicon nitride (SiNx), and the second layer may be formed as a hydrogen blocking layer.

The second layer may include aluminum oxide (AlOx).

The third layer may be formed to be thicker than the first layer.

The method of manufacturing a thin film transistor may further include performing at least one of light irradiation or heat treatment on the oxide semiconductor layer.

Forming the insulating layer and the gate electrode may include: forming an insulating material layer including an insulating material on the oxide semiconductor layer; forming the gate electrode on the insulating material layer; and forming the insulating layer by patterning the insulating material layer using the gate electrode as an etch mask and exposing a portion of the oxide semiconductor layer.

The exposed portion of the oxide semiconductor layer may suffer from reduction treatment to form an oxide semiconductor covered with the gate electrode, and the source electrode and the drain electrode which face each other based on the oxide semiconductor layer.

The method of manufacturing a thin film transistor may further include: forming an interlayer insulating layer on the gate electrode, in which the source electrode and the drain electrode may be disposed on the interlayer insulating layer and each of the source electrode and the drain electrode may be connected to the oxide semiconductor layer through a respective contact hole which is formed on the interlayer insulating layer.

Forming the insulating layer and the gate electrode may include: forming an insulating material layer on the oxide semiconductor layer; forming the gate electrode on the insulating material layer; and forming the insulating layer by patterning the insulating material layer using the gate electrode as a mask.

Edge portions of sides of each of the source electrode and the drain electrode may be formed to overlap the gate electrode.

According to embodiments of the present invention, it is possible to improve the reliability of the thin film transistor by forming the hydrogen blocking layer in the gate insulating layer.

### BRIEF DESCRIPTION OF THE DRAWINGS

FIGS. 1A and 1B are a cross-sectional view and a plan view of a thin film transistor display panel including a thin film transistor according to an embodiment.

FIGS. 2 to 9 are cross-sectional views sequentially illustrating a manufacturing method according to an embodiment for manufacturing the thin film transistor display panel illustrated in FIG. 1.

FIG. 10 is a cross-sectional view illustrating a thin film transistor according to an embodiment.

FIGS. 11 to 16 are cross-sectional views illustrating a method of manufacturing of a thin film transistor according to an embodiment.

FIG. 17 is a graph illustrating a hydrogen distribution of a thin film transistor according to Comparative Example.

FIG. 18 is a graph illustrating a hydrogen distribution of the thin film transistor according to an embodiment.

FIG. 19 is a graph illustrating a gate voltage-drain current according to Comparative Example.

FIG. 20 is a graph illustrating a gate voltage-drain current in the thin film transistor according to an embodiment.

### DETAILED DESCRIPTION OF CERTAIN INVENTIVE EMBODIMENTS

Hereinafter, certain embodiments will be described in detail with reference to the accompanying drawings. As those skilled in the art would realize, the described embodiments may be modified in various ways, without departing from the spirit or scope of the present invention. Embodiments introduced herein are provided to make the disclosed contents thorough and complete and sufficiently transfer the spirit of the present invention to those skilled in the art.

In the drawings, the thickness of layers, films, panels, regions, etc., may be exaggerated for clarity. It will be understood that when a layer is referred to as being “on” another layer or substrate, it can be directly on the other layer or substrate, or intervening them may also be present. Like reference numerals generally designate like elements throughout the specification.

Research into thin film transistors using an oxide semiconductor which has electron mobility and on/off ratio of current higher than the amorphous silicon and is cheaper and higher uniformity than the polysilicon has been conducted.

An insulating layer including silicon oxide (SiOx) and silicon nitride (SiNx) may be formed on the oxide semiconductor by chemical vapor deposition (CVD). In this case, as a silicon source, silane (SiH4) has been mainly used. In this case, reliability of the thin film transistor deteriorates as a conductive channel is formed due to an increase in carrier concentration in response to hydrogen doping.

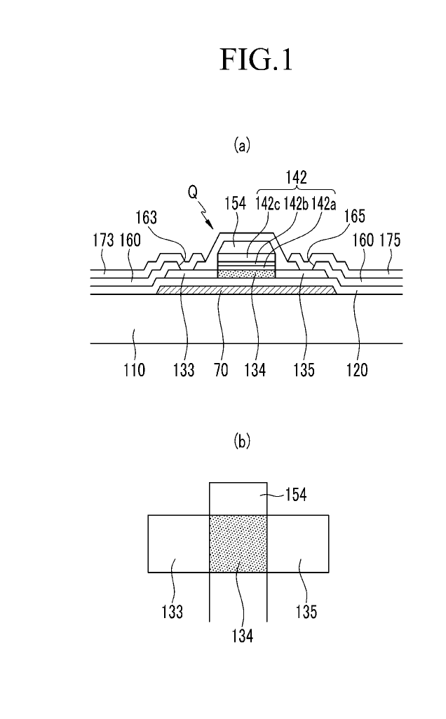

A thin film transistor and a thin film transistor display panel including the same according to an embodiment will be described with reference to FIG. 1.

FIGS. 1A and 1B are a cross-sectional view and a plan view of a thin film transistor display panel including a thin film transistor according to an embodiment.

Referring to FIG. 1A, a light blocking layer 70 may be disposed on an insulating substrate 110 which may be made of glass, plastic, or the like. The light blocking layer 70 blocks light from arriving at an oxide semiconductor layer (to be stacked later) to prevent semiconductor properties of an oxide semiconductor from being lost. Therefore, the light blocking layer 70 may be made of a material which does not transmit light in a wavelength band to be blocked so as to prevent the light from arriving at the oxide semiconductor. The light blocking layer 70 may be made of an organic insulating material, an inorganic insulating material, a conductive material such as, for example metal, or the like, and may be formed of a single layer or a multilayer.

The light blocking layer 70 may be omitted depending on conditions. In the case in which light is not irradiated from under the insulating substrate 110, for example, the light blocking layer 70 may be omitted when the thin film transistor according to an embodiment of the present invention is used in an organic light emitting diode display, and the like.

A buffer layer 120 is disposed on the light blocking layer 70. The buffer layer 120 may include insulating materials, such as, for example, silicon oxide (SiO2), silicon nitride (SiNx), and oxynitride silicon

The buffer layer 120 prevents impurities from flowing in the semiconductor (to be stacked later) from the insulating substrate 110 to be able to protect the semiconductor and improve the interfacial characteristics of the semiconductor.

A semiconductor layer 134, a source electrode 133, and a drain electrode 135 are disposed on the buffer layer 120.

The semiconductor layer 134 may be an oxide semiconductor layer 134. A material forming the oxide semiconductor layer 134 may be an metal oxide semiconductor and may be made of metal oxides such as, for example, zinc (Zn), indium (In), gallium (Ga), tin (Sn), or titanium (Ti), or a combination of metals such as zinc (Zn), indium (In), gallium (Ga), tin (Sn), and titanium (Ti) and/or their oxides. For example, the oxide semiconductor material may include at least one of zinc oxide (ZnO), zinc-tin oxide (ZTO), zinc-indium oxide (ZIO), indium oxide (InO), titanium oxide (TiO), indium-gallium-zinc oxide (IGZO), or indium-zinc-tin oxide (IZTO).

When the light blocking layer 70 is present, the oxide semiconductor layer 134 may be covered with the light blocking layer 70.

Referring to FIGS. 1A and 1B, the source electrode 133 and the drain electrode 135 are each disposed at both sides based on the oxide semiconductor layer 134 and are separated from each other. Further, the source electrode 133 and the drain electrode 135 are connected to the semiconductor layer 134.

The source electrode 133 and the drain electrode 135 have conductivity and may include the same material as the semiconductor material forming the oxide semiconductor layer 134 and a reduced semiconductor material. Metals such as indium (In) included in the semiconductor material may be educed on surfaces of the source electrode 133 and the drain electrode 135.

An insulating layer 142 is disposed on the oxide semiconductor layer 134. The insulating layer 142 may cover the oxide semiconductor layer 134. Further, the insulating layer 142 may not substantially overlap the source electrode 133 or the drain electrode 135.

According to an embodiment, the insulating layer 142 includes a first layer 142a, a second layer 142b, and a third layer 142c. The first layer 142a forms an interface with the oxide semiconductor layer 134 and may be made of silicon oxide (SiOx) to minimize a trap density at the interface. Aluminum oxide (Al2O3) may be used as a material of the second layer 142b to be described below, in which the aluminum oxide has an ion bonding characteristic as compared with the silicon oxide (SiO2). Therefore, when the second layer 142b is formed just on the oxide semiconductor layer 134 without the first layer 142a, bonding energy of the material forming the oxide semiconductor layer 134 may be shifted. On the contrary, the silicon oxide (SiO2) having a covalent bonding characteristic less affects the oxide semiconductor layer 134, thereby forming the stable interface. The first layer 142a may have a thickness from about 100 Å to about 1,000 Å. When the thickness of the first layer is formed to be smaller than 100 Å, uniformity of the layer may be reduced in a large area.

The second layer 142b is disposed on the first layer 142a and is formed as the hydrogen blocking layer. The second layer 142b prevents a carrier concentration from increasing due to diffusion and doping of hydrogen generated during a deposition process of the third layer 142c (to be formed later) to the oxide semiconductor layer 134. When the carrier concentration is increased due to the doping of the oxide semiconductor layer 134 with hydrogen, a conductive channel is formed to reduce the reliability of the thin film transistor.

In order for the second layer 142b to function as the hydrogen blocking layer, the second layer 142b may be made of aluminum oxide (AlOx). The second layer 142b may have a thickness from about 100 A to about 1,000 A, such as for example, between 100 Å and 300 Å.

The third layer 142c is disposed on the second layer 142b and is formed to be thicker than the first layer 142a. The third layer 142c may be made of silicon nitride (SiNx) and is made to be sufficiently thick to secure a physical thickness so as to function as the insulating layer. The third layer 142c has the thickness to prevent an electrical short from occurring due to the insulating layer 142. The third layer 142c may have a thickness from about 100 Å to about 4,000 Å.

When the first layer 142a is deposited just on the oxide semiconductor layer 134 at high temperature, the oxide semiconductor layer 134 may be damaged. However, according to an embodiment, since the third layer 142c is formed to have a sufficient thickness in terms of the short prevention of the insulating layer 142, the first layer 142a may be formed to be relatively thin. Therefore, since the first layer 142a has the reduced thickness, the first layer 142a may be deposited within a short period of time even though a process temperature is increased, thereby minimizing the damage of the oxide semiconductor layer 134.

A gate electrode 154 is disposed on the insulating layer 142. An edge boundary of the gate electrode 154 and an edge boundary of the insulating layer 142 may be aligned to substantially match each other.

Referring to FIGS. 1A and 1B, the gate electrode 154 includes a portion overlapping the oxide semiconductor layer 134 and the oxide semiconductor layer 134 is covered with the gate electrode 154. The source electrode 133 and the drain electrode 135 are disposed at both sides of the oxide semiconductor layer 134 based on the gate electrode 154, and the source electrode 133 and the drain electrode 135 may not substantially overlap the gate electrode 154. Therefore, a parasitic capacitance between the gate electrode 154 and the source electrode 133, or a parasitic capacitance between the gate electrode 154 and the drain electrode 135 may be reduced.

The gate electrode 154 may be made of at least one metal such as, for example aluminum (Al), silver (Ag), copper (Cu), molybdenum (Mo), chromium (Cr), tantalum (Ta), and titanium (Ti) or an alloy thereof, and the like. The gate electrode 154 may have a single layer structure or a multilayer structure. An example of the multilayer may include a double layer formed of a lower layer such as titanium (Ti), tantalum (Ta), molybdenum (Mo), and ITO and an upper layer such as copper (Cu), a triple layer of molybdenum (Mo)-aluminum (Al)-molybdenum (Mo), and the like. However, the gate electrode 154 may be made of various metals or conductors in addition to the above materials.

According to an embodiment, a boundary between the oxide semiconductor layer 134 and the source electrode 133, or a boundary between the oxide semiconductor layer 134 and the drain electrode 135 may be substantially aligned with an edge boundary of the gate electrode 154 and the insulating layer 142 so as to match each other. However, the boundary between the oxide semiconductor layer 134 and the source electrode 133 or the drain electrode 135 may be disposed a little more inwardly than the edge boundary between the gate electrode 154 and the insulating layer 142.

The gate electrode 154, the source electrode 133, and the drain electrode 135 form the thin film transistor (TFT) Q along with the oxide semiconductor layer 134 and the channel of the thin film transistor is formed on the oxide semiconductor layer 134.

A passivation layer 160 is disposed on the gate electrode 154, the source electrode 133, the drain electrode 135, and the buffer layer 120. The passivation layer 160 may be made of inorganic insulating materials such as silicon nitride and silicon oxide, organic insulating materials, or the like. The passivation layer 160 may include a contact hole 163 which exposes the source electrode 133 and a contact hole 165 which exposes the drain electrode 135.

A data input electrode 173 and a data output electrode 175 may be disposed on the passivation layer 160. The data input electrode 173 may be electrically connected to the source electrode 133 of the thin film transistor Q through the contact hole 163 of the passivation layer 160, and the data output electrode 175 may be electrically connected to the drain electrode 135 of the thin film transistor Q through the contact hole 165 of the passivation layer 160.

A color filter (not illustrated) or an organic layer (not illustrated) made of an organic material may be further disposed on the passivation layer 160 and the data input electrode 173 and the data output electrode 175 may also be disposed thereon.

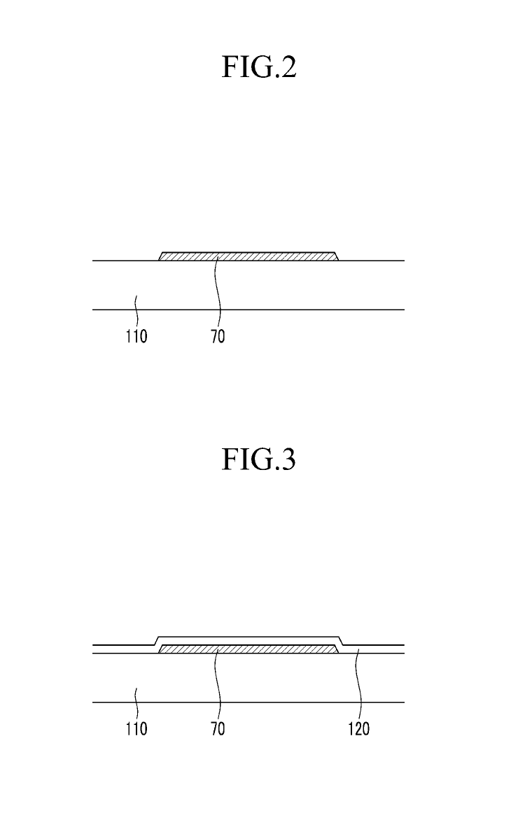

Next, the manufacturing method according to an embodiment to manufacture the thin film transistor display panel illustrated in FIG. 1 will be described with reference to FIGS. 2 to 9 along with FIG. 1 described above.

FIGS. 2 to 9 are cross-sectional views sequentially illustrating the manufacturing method according to an embodiment for manufacturing the thin film transistor display panel illustrated in FIG. 1.

Referring first to FIG. 2, the light blocking layer 70 made of the organic insulating materials, the inorganic insulating materials, and the conductive materials such as, for example, metal, is formed on the insulating substrate 110 which may be made of, for example, glass, plastic, or the like. A step of forming the light blocking layer 70 may be omitted depending on conditions.

Next, referring to FIG. 3, the buffer layer 120 made of the insulating materials such as, for example, silicon oxide (SiO2), silicon nitride (SiNx), and oxynitride silicon is formed on the light blocking layer 70 by the chemical vapor deposition (CVD), and the like.

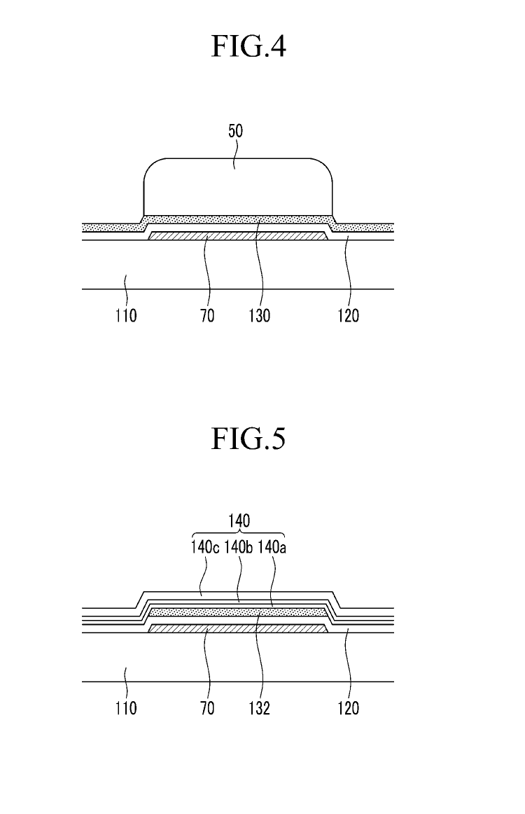

Next, referring to FIG. 4, a semiconductor material layer 130 which may made of oxide semiconductor materials such as, for example, zinc oxide (ZnO), zinc-tin oxide (ZTO), zinc-indium oxide (ZIO), indium oxide (InO), titanium oxide (TiO), indium-gallium-zinc oxide (IGZO), and indium-zinc-tin oxide (IZTO) is applied on the buffer layer 120.

Next, a photosensitive layer, such as photoresist, is applied on the semiconductor material layer 130 and then exposed, thereby forming a photosensitive layer pattern 50. The photosensitive layer pattern 50 may overlap at least a portion of the light blocking layer 70.

Next, referring to FIG. 5, the semiconductor material layer 130 is etched by using the photosensitive layer pattern 50 as a mask, thereby forming the semiconductor pattern 132.

Next, the insulating material layer 140 is formed on the semiconductor pattern 132 and the buffer layer 120. The insulating material layer 140 is formed by sequentially stacking a first insulating material layer 140a, a second insulating material layer 140b on the first insulating material layer 140a, and a third insulating material layer 140c on the second insulating material layer 140b. The first insulating material layer 140a may be made of silicon oxide (SiOx), the second insulating material layer 140b may be made of aluminum oxide (AlOx), and the third insulating material layer 140c may be made of silicon nitride (SiNx), for example.

According to an embodiment, the first insulating material layer 140a may be deposited on the semiconductor pattern 132 by using a chemical vapor deposition (CVD) in a process temperature range from about 100° C. to about 400° C. The second insulating material layer 140b may be deposited on the first insulating material layer 140a by sputtering or atomic layer deposition (ALD). When the second insulating material layer 140b is formed by an atomic layer deposition, since the process time is long, the process is costly, and mass production is poor, and therefore the second insulating material layer 140b may be deposited by using sputtering.

The third insulating material layer 140c may be deposited on the second insulating material layer 140b by using a chemical vapor deposition (CVD) in the process temperature range from about 100° C. to about 400° C.

Next, the semiconductor pattern 132 may be light irradiated or heat treated. The defects of the semiconductor pattern 132 are reduced by the light irradiation or heat treatment process, thereby improving the reliability.

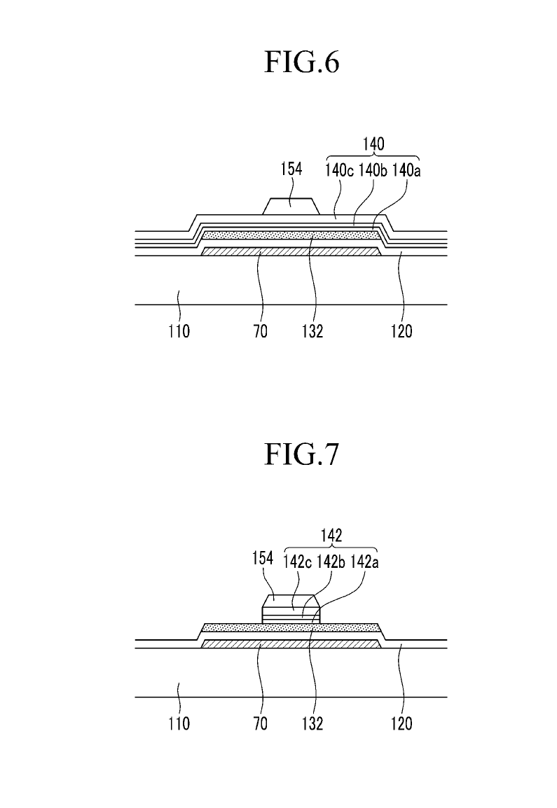

Next, referring to FIG. 6, the conductive material such as for example metal is stacked on the insulating material layer 140 and then patterned to form the gate electrode 154. The gate electrode 154 is formed to cross and penetrate through a middle portion of the semiconductor pattern 132 so that two portions of the semiconductor pattern 132 disposed at both sides of the overlapping portion of the gate electrode 154 and the semiconductor pattern 132 are not covered with the gate electrode 154.

Next, referring to FIG. 7, the insulating material layer 140 is patterned using the gate electrode 154 as an etching mask to form the insulating layer 142. The insulating layer 142 has a structure in which a first insulating layer 142a, a second insulating layer 142b, and a third insulating layer 142c are sequentially stacked.

Therefore, the gate electrode 154 and the insulating layer 142 may have substantially the same plane shape. Further, two portions of both sides of the semiconductor pattern 132 which are not covered with the gate electrode 154 are exposed.

As the patterning method of the insulating material layer 140, a dry etch method may be used and the buffer layer 120 may not be etched by controlling etch gas or etch time.

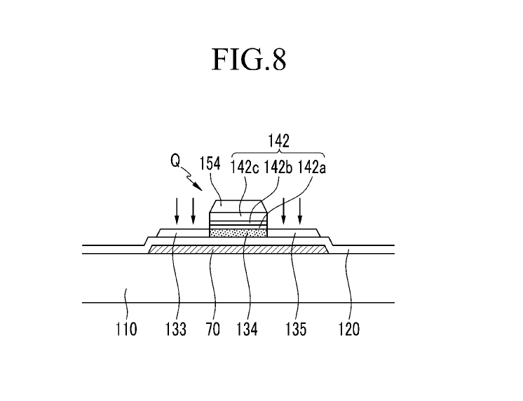

Next, referring to FIG. 8, the exposed two portions of the semiconductor pattern 132 suffer from reduction treatment to form the source electrode 133 and the drain electrode 135 having conductivity. Further, the semiconductor pattern 132 which is covered with the insulating layer 142, and is not reduced, becomes the oxide semiconductor layer 134. Therefore, the gate electrode 154, the source electrode 133, and the drain electrode 135 form the thin film transistor Q along with the oxide semiconductor layer 134.

As a reduction treatment method of the exposed semiconductor pattern 132, a heat treatment method may also be used in a reduction atmosphere and a plasma treatment method using gas plasma such as hydrogen (H2), helium (He), phosphine (PH3), ammonia, (NH3), silane (SiH4), methane (CH4), acetylene (C2H2), diborane (B2H6), carbon dioxide (CO2), germane (GeH4), hydrogen selenide (H2Se), hydrogen sulfide (H2S), argon (Ar), nitrogen (N2), nitrogen oxide (N2O), and fluoroform (CHF3) may also be used. At least a portion of the semiconductor material forming the reduction treated and exposed semiconductor pattern 132 is reduced and thus only the metal bonding may remain. Therefore, the reduced semiconductor pattern 132 has conductivity.

At the time of the reduction treatment of the semiconductor pattern 132, metal components of the semiconductor material, such as, for example, indium (In), and the like may be educed on a surface of an upper portion of the semiconductor pattern 132. A thickness of the educed metal layer may be about 200 nm or less.

According to an embodiment, the boundary between the semiconductor layer 134 and the source electrode 133, or the boundary between the semiconductor layer 134 and the drain electrode 135 may be substantially aligned with the edge boundary of the gate electrode 154 and the insulating layer 142 so as to match each other. However, at the time of the reduction treatment of the semiconductor pattern 132, the semiconductor pattern 132 under the edge portion of the insulating layer 142 may be reduced to some extent, such that the boundary between the semiconductor layer 134 and the source electrode 133 or the drain electrode 135 may be deposited more inwardly than the edge boundary between the gate electrode 154 and the insulating layer 142.

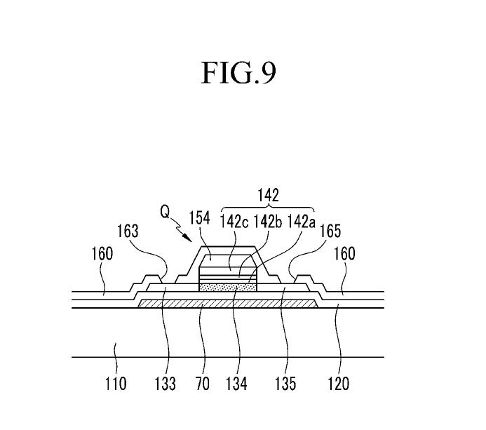

Next, referring to FIG. 9, the insulating material is applied on the gate electrode 154, the source electrode 133, the drain electrode 135, and the buffer layer 120 to form the passivation layer 160. Next, the passivation layer 160 is patterned to form the contact hole 163 exposing the source electrode 133, and the contact hole 165 exposing the drain electrode 135.

Next, as illustrated in FIG. 1, a data input electrode 173 and a data output electrode 175 may be formed on the passivation layer 160.

In the thin film transistor Q according to an embodiment, since the gate electrode 154 and the source electrode 133 or the drain electrode 135 do not substantially overlap each other, the parasitic capacitance between the gate electrode 154 and the source electrode 133, or the parasitic capacitance between the gate electrode 154 and the drain electrode 135 may be very small. Therefore, the on/off characteristic as the switching element of the thin film transistor Q may be improved.

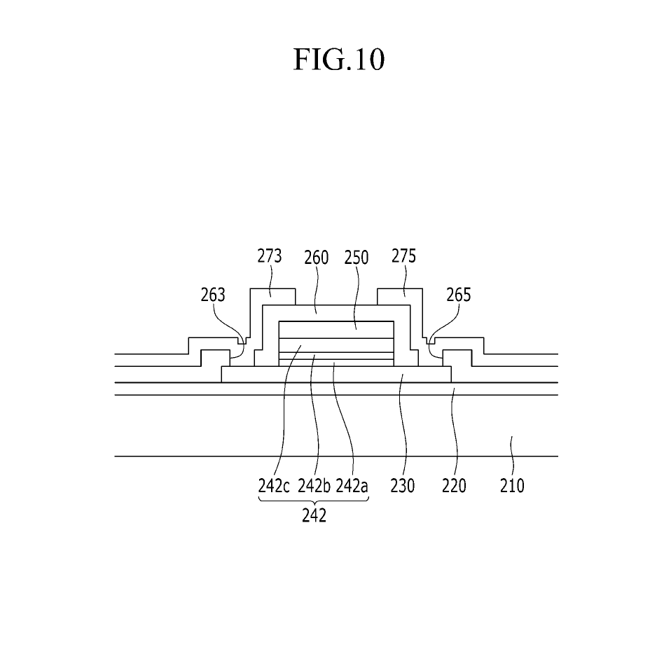

FIG. 10 is a cross-sectional view illustrating a thin film transistor according to an embodiment.

Referring to FIG. 10, a buffer layer 220 is disposed on an insulating substrate 210 which may be made of, for example, glass, plastic, or the like. The buffer layer 220 may include insulating materials, such as, for example, silicon oxide (SiO2), silicon nitride (SiNx), and oxynitride silicon

FIG. 10 illustrates that the buffer layer 220 is formed of a single layer, but the buffer layer 220 may be formed as a multilayer. The buffer layer 220 prevents impurities from flowing in the semiconductor (to be stacked later) from the insulating substrate 210 to be able to protect the semiconductor and improve the interfacial characteristics of the semiconductor.

An oxide semiconductor layer 230 is disposed on the buffer layer 220. The oxide semiconductor layer 230 may be made of an metal oxide semiconductor and may be made of metal oxides such as, for example, zinc (Zn), indium (In), gallium (Ga), tin (Sn), and titanium (Ti) or a combination of metals such as zinc (Zn), indium (In), gallium (Ga), tin (Sn), and titanium (Ti) and their oxides. For example, the oxide semiconductor material may include at least one of zinc oxide (ZnO), zinc-tin oxide (ZTO), zinc-indium oxide (ZIO), indium oxide (InO), titanium oxide (TiO), indium-gallium-zinc oxide (IGZO), and indium-zinc-tin oxide (IZTO).

An insulating layer 242 is disposed on the oxide semiconductor layer 230. According to an embodiment, the insulating layer 242 includes a first layer 242a, a second layer 242b, and a third layer 242c. The first layer 242a forms an interface with the oxide semiconductor layer 230 and may be made of, for example, silicon oxide (SiOx). The first layer 242a may have a thickness from about 100 Å to about 1,000 Å. When the thickness of the first layer is formed to be smaller than about 100 Å, uniformity of the layer may be reduced in a large area.

The second layer 242b is disposed on the first layer 242a and is formed as a hydrogen blocking layer. The second layer 242b prevents a carrier concentration from increasing due to diffusion and doping of hydrogen generated during a deposition process of the third layer 242c (to be formed later) to the oxide semiconductor layer 230. When the carrier concentration is increased due to the doping of the oxide semiconductor layer 230 with hydrogen, a conductive channel is formed to reduce the reliability of the thin film transistor.

In order for the second layer 242b to function as the hydrogen blocking layer, the second layer 242b may be made of aluminum oxide (AlOx). The second layer 242b may have a thickness from about 100 Å to about 1,000 Å, such as for example from about 100 Å to about 300 Å.

The third layer 242c is disposed on the second layer 242b and is formed to be thicker than the first layer 242a. The third layer 242c may be made of silicon nitride (SiNx) and needs to be sufficiently thick to secure a physical thickness so as to function as the insulating layer. The third layer 242c has the thickness to prevent electrical short from occurring due to the insulating layer 242. The third layer 242c may have a thickness from about 100 Å to about 4,000 Å.

A gate electrode 250 is disposed on the insulating layer 242. An edge boundary of the gate electrode 250 and an edge boundary of the insulating layer 242 may be aligned to substantially match each other.

The gate electrode 250 includes a portion overlapping the oxide semiconductor layer 230 and the oxide semiconductor layer 230 is covered with the gate electrode 250.

The gate electrode 250 may be made of metals such as, for example, aluminum (Al), silver (Ag), copper (Cu), molybdenum (Mo), chromium (Cr), tantalum (Ta), and titanium (Ti) or an alloy thereof, and the like. The gate electrode 154 may have a single layer structure or a multilayer structure. An example of the multilayer may include a double layer formed of a lower layer such as titanium (Ti), tantalum (Ta), molybdenum (Mo), and ITO, and an upper layer such as copper (Cu), a triple layer of molybdenum (Mo)-aluminum (Al)-molybdenum (Mo), and the like. However, the gate electrode 250 may be made of various metals or conductors in addition to the above materials.

An interlayer insulating layer 260 is disposed on the gate electrode 250, the oxide semiconductor layer 230, and the buffer layer 220. The interlayer insulating layer 260 may be made of inorganic insulating materials such as silicon nitride and silicon oxide, organic insulating materials, or the like. The interlayer insulating layer 260 is provided with contact holes 263 and 265 which expose each of the source electrode 273 and the drain electrode 275.

The source electrode 273 and the drain electrode 275 are disposed on the interlayer insulating layer 260 while being spaced apart from each other. The source electrode 273 and the drain electrode 275 each may be electrically connected to the oxide semiconductor layer 230 through the contact holes 263 and 265 which are formed on the interlayer insulating layer 260.

As illustrated in FIG. 10, an edge portion of one side of the source electrode 273 may overlap the gate electrode 250 and an edge portion of one side of the drain electrode 275 may overlap the gate electrode 250. However, embodiments are not necessarily limited thereto, and the source electrode 273 and the drain electrode 275 may be formed so as not to substantially overlap the gate electrode 250.

The gate electrode 250, the source electrode 273, and the drain electrode 275 form the thin film transistor (TFT) along with the oxide semiconductor layer 230 and the channel of the thin film transistor is formed on the oxide semiconductor layer 230.

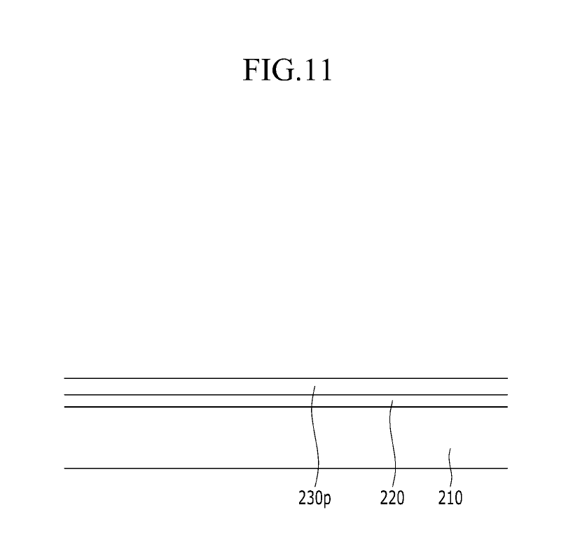

Next, the manufacturing method according to an embodiment to manufacture the thin film transistor illustrated in FIG. 10 will be described with reference to FIGS. 11 to 16 along with FIG. 10 described above. FIGS. 11 to 16 are cross-sectional views illustrating a method of manufacturing a thin film transistor according to an embodiment.

Referring first to FIG. 11, the buffer layer 220 made of the insulating materials such as for example silicon oxide (SiO2), silicon nitride (SiNx), and oxynitride silicon is formed on the insulating substrate 210 made of glass, plastic, or the like by the chemical vapor deposition (CVD), and the like.

An oxide semiconductor material layer 230p, which may be made of oxide semiconductor materials such as for example zinc oxide (ZnO), zinc-tin oxide (ZTO), zinc-indium oxide (ZIO), indium oxide (InO), titanium oxide (TiO), indium-gallium-zinc oxide (IGZO), and indium-zinc-tin oxide (IZTO), is applied on the buffer layer 220 by using the sputtering, and the like. In this case, the oxide semiconductor material layer 230p may be in an amorphous state.

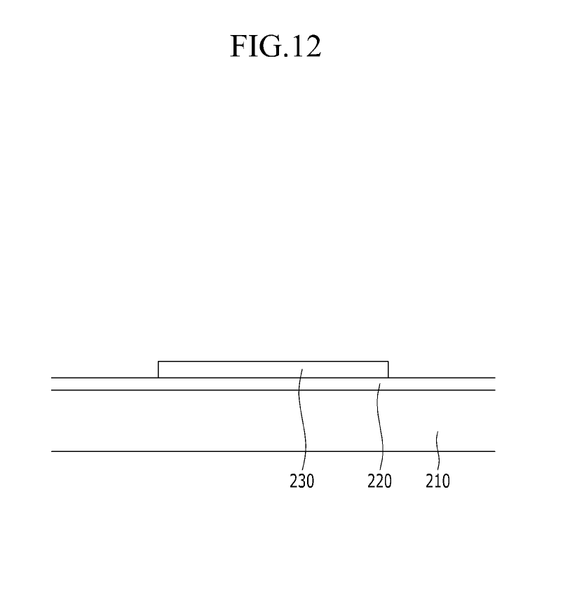

Referring to FIG. 12, the oxide semiconductor material layer 230p is etched using the photosensitive layer pattern (not illustrated) as the mask to form the oxide semiconductor layer 230.

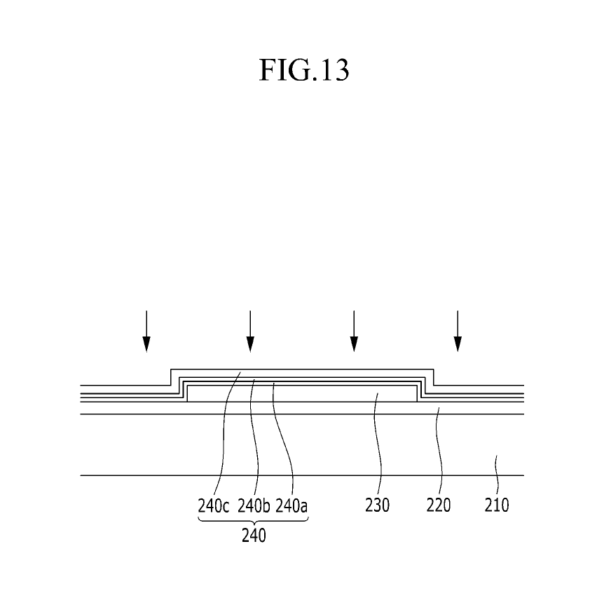

Referring to FIG. 13, the insulating material layer 240 is formed to cover the oxide semiconductor layer 230. The insulating material layer 240 is formed by sequentially stacking a first insulating material layer 240a, a second insulating material layer 240b on the first insulating material layer 240a, and a third insulating material layer 240c on the second insulating material layer 240b. The first insulating material layer 240a may be made of silicon oxide (SiOx), the second insulating material layer 240b may be made of aluminum oxide (AlOx), and the third insulating material layer 240c may be made of silicon nitride (SiNx).

According to an embodiment, the first insulating material layer 240a may be deposited on the oxide semiconductor layer 230 by using the chemical vapor deposition (CVD) in a process temperature range from about 100° C. to about 400° C. The second insulating material layer 240b may be deposited on the first insulating material layer 240a by sputtering or atomic layer deposition (ALD). When the second insulating material layer 240b is formed by the atomic layer deposition, since the process time is long and, cost is consumed, and mass production is poor, the second insulating material layer 240b may be deposited by using sputtering.

The third insulating material layer 240c may be deposited on the second insulating material layer 240b by using the chemical vapor deposition (CVD) in the process temperature range from about 100° C. to about 400° C.

As illustrated by the arrows in FIG. 13, a laser is irradiated toward the oxide semiconductor layer 230 to reduce the defects of the oxide semiconductor layer 230, thereby improving the reliability. Instead of the laser irradiation method, the oxide semiconductor layer 230 may alternatively be heat treated.

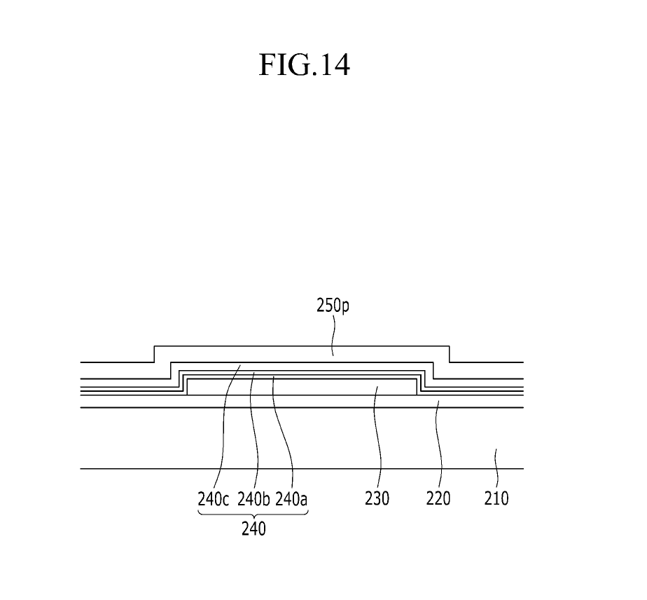

Referring to FIG. 14, the gate electrode material layer 250p is applied on the insulating material layer 240. The gate electrode material layer 250p may be made of a conductive material such as for example metal.

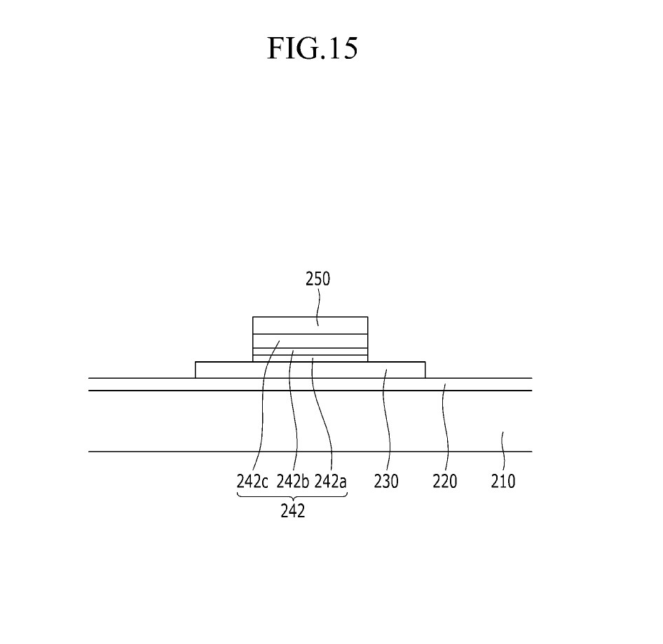

Referring to FIG. 15, the gate electrode 250 may be formed by patterning the gate electrode material layer 250p and the insulating layer 242 may be formed by patterning the insulating material layer 240 using the gate electrode 250 as the etch mask. In this case, the insulating layer 242 and the gate electrode 250 have the same plane pattern and the edge boundary of the gate electrode 250 and the edge boundary of the insulating layer 242 may be aligned to substantially match each other.

The width of the gate electrode 250 may be smaller than that of the oxide semiconductor layer 230.

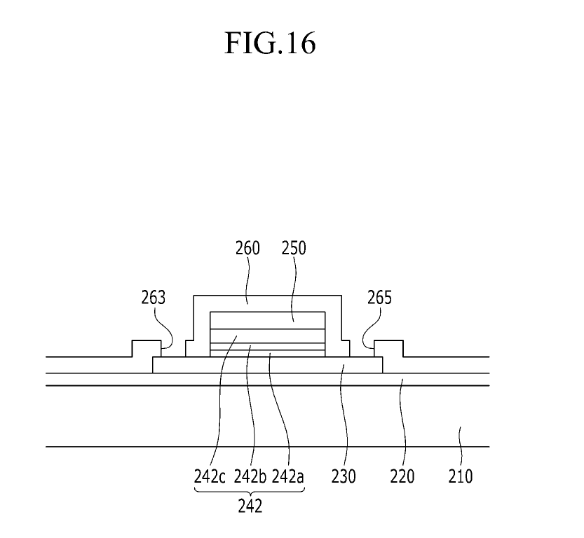

Referring to FIG. 16, the interlayer insulating layer 260 is disposed on the gate electrode 250, the oxide semiconductor layer 230, and the buffer layer 220. The interlayer insulating layer 260 may be made of inorganic insulating materials such as for example silicon nitride and silicon oxide, organic insulating materials, or the like. Next, the contact holes 263 and 265 which expose a portion of the oxide semiconductor layer 230 are formed by patterning the interlayer insulating layer 260.

Next, the thin film transistor according to an embodiment illustrated in FIG. 10 may be formed by forming the source electrode 273 and the drain electrode 275 on the interlayer insulating layer 260. In this case, the source electrode 273 and the drain electrode 275 are each formed to be electrically connected to the oxide semiconductor layer 230 through the contact holes 263 and 265.

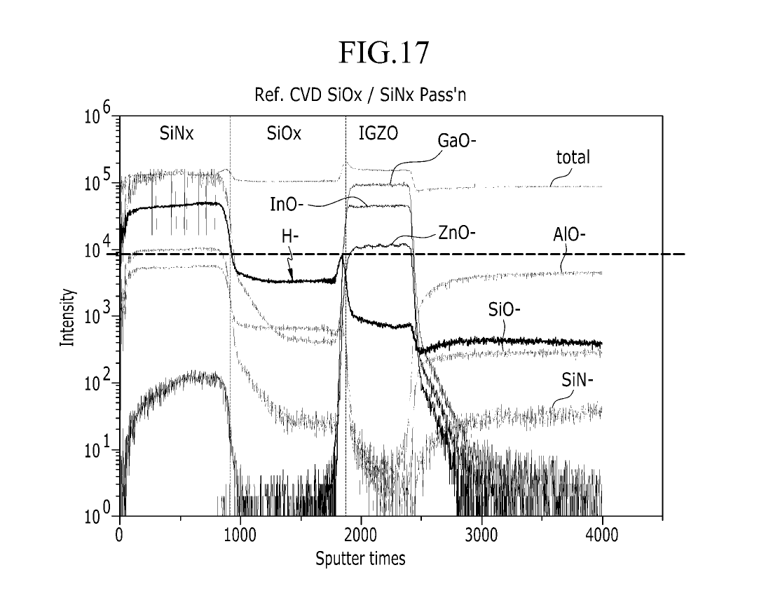

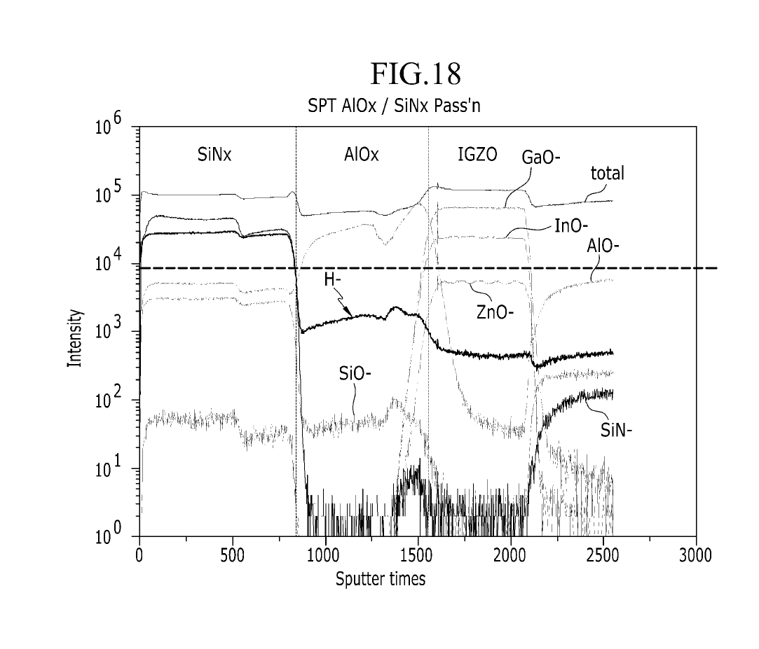

FIG. 17 is a graph illustrating a hydrogen distribution of a thin film transistor according to Comparative Example and FIG. 18 is a graph illustrating a hydrogen distribution of the thin film transistor according to an embodiment.

The following Table 1 is a result showing secondary ion mass spectroscopy (SIMS) according to Comparative Example and Embodiment to test the hydrogen blocking effect as illustrated in FIGS. 17 and 18. Comparative Example shows one obtained by measuring the hydrogen distribution in the layer structure in which a layer made of silicon oxide and a layer made of silicon nitride are sequentially stacked on the indium-gallium-zinc oxide layer (IGZO) and Embodiment shows one obtained by measuring the hydrogen distribution in the layer structure in which a layer made of aluminum oxide and a layer made of silicon nitride are sequentially stacked on the indium-gallium-zinc oxide layer (IGZO).

Referring to FIG. 17 and the Comparative Example column of Table 1, among all the elements, 3.09% of hydrogen exists at the interface between the IGZO layer and the layer made of silicon oxide, while Referring to FIG. 18 and the Embodiment column of Table 1, among all the elements, 1.04% of hydrogen exists at the interface between the IGZO layer and the layer made of aluminum oxide. That is, comparing to the Comparative Example, a hydrogen amount of the interface of the oxide semiconductor layer is significantly reduced in the thin film transistor according to Embodiment, thereby improving the reliability.

TABLE 1

| Layer | Comparative Example | Embodiment |
|---|---|---|
| IGZO | 0.50 at % | 0.39 at % |
| Interface | 3.09 at % | 1.04 at % |
| AlOx | — | 2.84 at % |
| SiOx | 3.32 at % | — |
| SiNx | 34.5 at % | 34.5 at % |

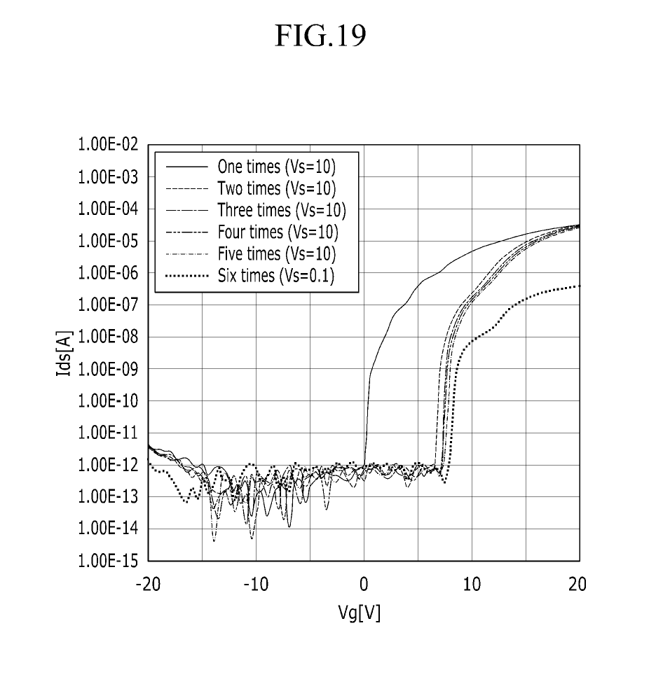

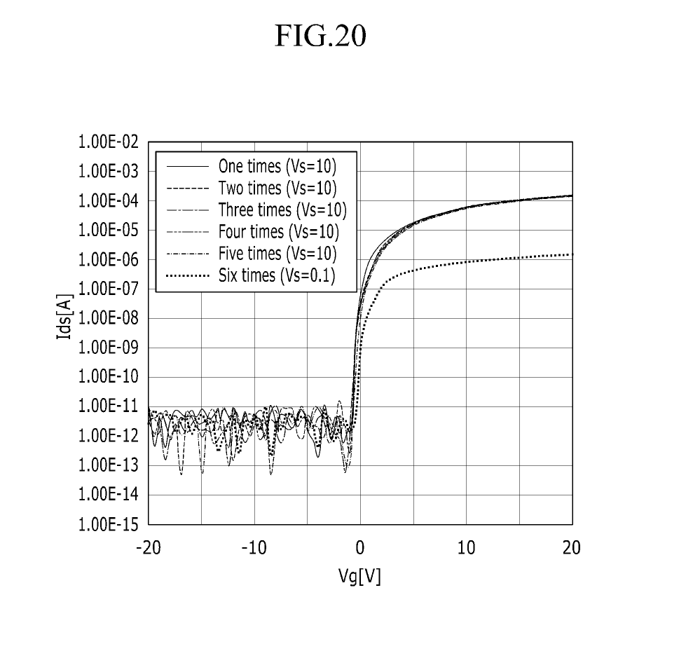

FIG. 19 is a graph illustrating a gate voltage-drain current according to Comparative Example and FIG. 20 is a graph illustrating a gate voltage-drain current in the thin film transistor according to an embodiment.

Comparative Example shows one obtained by measuring the reliability of the thin film transistor in which the insulating layer is made only of silicon oxide (SiOx) and Embodiment shows one obtained by measuring the reliability of the thin film transistor in which the insulating layer of a triple layer made of silicon oxide (SiOx), aluminum oxide (AlOx), and silicon nitride (SiNx) is formed.

It may be appreciated that that referring to FIG. 19, according to Comparative Example, a shift frequently occurs as a result of measuring the gate voltage-drain current several times, but referring to FIG. 20, according to Embodiment, since the shift is small, the initial reliability of the thin film transistor is improved.

While this invention has been described in connection with certain embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor, comprising:
a substrate;
an oxide semiconductor layer disposed on the substrate;
a source electrode and a drain electrode each connected to the oxide semiconductor layer and facing each other with respect to the oxide semiconductor layer;
an insulating layer disposed on the oxide semiconductor layer, the insulating layer comprising a first layer, a second layer, and a third layer sequentially stacked, wherein the first layer comprises silicon oxide (SiOx), the second layer is a hydrogen blocking layer and the third layer comprises silicon nitride (SiNx); and
a gate electrode disposed on the insulating layer

2. The thin film transistor of claim 1, wherein:
the second layer comprises aluminum oxide (AlOx).

3. The thin film transistor of claim 2, wherein:
the third layer is thicker than the first layer.

4. The thin film transistor of claim 3, wherein:
edge boundaries between the insulating layer and the gate electrode are aligned with each other.

5. The thin film transistor of claim 4, wherein:
edge boundaries between the gate electrode and the oxide semiconductor layer are aligned with each other.

6. The thin film transistor of claim 5, wherein:
the source electrode and the drain electrode each include a material obtained by reducing a material forming the oxide semiconductor layer.

7. The thin film transistor of claim 6, wherein:
the oxide semiconductor layer, the source electrode and the drain electrode are disposed at a same layer.

8. The thin film transistor of claim 4, further comprising:
an interlayer insulating layer disposed on the gate electrode, wherein the source electrode and the drain electrode are disposed on the interlayer insulating layer and each of the source electrode and the drain electrode is connected to the oxide semiconductor layer through a respective contact hole formed on the interlayer insulating layer.

9. The thin film transistor of claim 8, wherein:
edge portions of each of the source electrode and the drain electrode overlap the gate electrode.

10. The thin film transistor of claim 1, further comprising:
a buffer layer disposed between the substrate and the oxide semiconductor layer.

11. A method of manufacturing a thin film transistor, comprising:
forming an oxide semiconductor layer on a substrate;
forming an insulating layer by sequentially stacking a first layer, a second layer, and a third layer on the oxide semiconductor layer, wherein the first layer is formed by chemical vapor deposition, the second layer is formed by sputtering or atomic layer deposition, and the third layer is formed by chemical vapor deposition;
forming a gate electrode on the insulating layer; and
forming a source electrode and a drain electrode connected to the oxide semiconductor layer and facing each other with respect to the oxide semiconductor layer

12. The method of claim 11, wherein:
the first layer comprises silicon oxide (SiOx), the third layer comprises silicon nitride (SiNx), and the second layer is formed as a hydrogen blocking layer.

13. The method of claim 12, wherein:
the second layer comprises aluminum oxide (AlOx).

14. The method of claim 13, wherein:
the third layer is formed to be thicker than the first layer.

15. The method of claim 14, further comprising:
performing at least one of light irradiation or heat treatment on the oxide semiconductor layer.

16. The method of claim 15, wherein:
forming the insulating layer and the gate electrode comprises:
forming an insulating material layer including an insulating material on the oxide semiconductor layer;
forming the gate electrode on the insulating material layer; and
forming the insulating layer by patterning the insulating material layer using the gate electrode as an etch mask and exposing a portion of the oxide semiconductor layer.

17. The method of claim 16, wherein:
the exposed portion of the oxide semiconductor layer suffers from reduction treatment to form an oxide semiconductor covered with the gate electrode, and the source electrode and the drain electrode which face each other based on the oxide semiconductor layer.

18. The method of claim 15, further comprising:
forming an interlayer insulating layer on the gate electrode, wherein the source electrode and the drain electrode are disposed on the interlayer insulating layer and each of the source electrode and the drain electrode is connected to the oxide semiconductor layer through a respective contact hole formed on the interlayer insulating layer.

19. The method of claim 18, wherein:
forming the insulating layer and the gate electrode includes:
forming an insulating material layer on the oxide semiconductor layer;
forming the gate electrode on the insulating material layer; and
forming the insulating layer by patterning the insulating material layer using the gate electrode as a mask.

20. The method of claim 19, wherein:
edge portions of sides of each of the source electrode and the drain electrode are formed to overlap the gate electrode.
